(19) United States
(12) Patent Application Publication
(10) Pub. No.: US 2023/0217665 A1
(43) Pub. Date: Jul. 6, 2023

(54) SOLAR CELL DEVICE

(71) Applicant: Technion Research & Development Foundation Limited, Haifa (IL)

(72) Inventors: Himanshu SHEKHAR, Cambridge (GB); Nir TESSLER, Zichron Yaakov (IL)

(21) Appl. No.: 17/999,760

(22) PCT Filed: May 26, 2021
(86) PCT No.: PCT/IL2021/050620

§ 371 Date: Nov. 23, 2022

Related U.S. Application Data
(60) Provisional application No. 63/030,033, filed on May 26, 2020.

(51) Int. Cl. H10K 30/40; H10K 30/30; H10K 30/57

(52) U.S. Cl. CPC H10K 30/40; H10K 30/30; H10K 30/57; H10K 85/211

(57) ABSTRACT

A solar cell device is presented. The solar cell device comprises a layered structure comprising an electron transport layer and a hole transport layer and a heterojunction interface region between the electron transport and hole transport layers configured to define at least one charge generation region forming at least one junction between them, wherein at least one of the electron transport layer and the hole transport layer comprises at least one modulated doping layer at a predetermined distance from said at least one junction, said at least one modulated doping layer thereby inducing variation of an energy band structure at a vicinity of said at least one junction generating electric field applied to charge carriers increasing efficiency of generation and/or collection of the charge carriers.

### TECHNOLOGICAL FIELD

The present invention is in the field of solar energy harvesting and relates to a solar cell device.

### BACKGROUND ART

References considered to be relevant as background to the presently disclosed subject matter are listed below:
1. US 2013/0220407;
2. H. F. Lu, L. Fu, G. Jolley, H. H. Tan and C. Jagadish, Improved performance of InGaAs/GaAs quantum dot solar cells using Si-modulation doping, COMMAD 2012, 2012, pp. 127-128;
3. P. Lam, S. Hatch, J. Wu, M. Tang, V. G. Dorogan, Y. I. Mazur, G. J. Salamo, I. Ramiro, A. Seeds and H. Liu, Nano Energy, 2014, 6, 159-166.
4. E. v. Hauff, E. d. Como and S. Ludwigs, Adv. Polym. Sci., 2017, 272, 109-138;
5. Y. Lin, Y. Firdaus, M. I. Nugraha, F. Liu, S. Karuthedath, A.-H. Emwas, W. Zhang, A. Seitkhan, M. Neophytou, H. Faber, E. Yengel, I. McCulloch, L. Tsetseris, F. Laquai and T. D. Anthopoulos, Adv. Sci., 2020, 7, 1903419;
6. D. Zhang, J. Wang, X. Zhang, J. Zhou, S.-U. Zafar, H. Zhou and Y. Zhang, J. Mater. Chem. C, 2020, 8, 158-164.

Acknowledgement of the above references herein is not to be inferred as meaning that these are in any way relevant to the patentability of the presently disclosed subject matter.

### BACKGROUND

The power conversion efficiency (PCE) of organic solar cells is greatly influenced by the rate at which coulombically bound photogenerated charge pairs dissociate into free carriers at cell's donor-acceptor junction. In solar cells, the built-in electric field at the maximum power point, i.e., close to open-circuit voltage or flat-band condition, is close to zero. This suggests strong competition between dissociation and separation of charges with recombination losses. As a result, solar cell using high open circuit voltage (high V_{OC} cells) tends to have relatively low fill factors, while the fill factor is theoretically supposed to go up with the open circuit voltage.

Bulk heterojunction (BHJ) organic solar cells have been recently gaining momentum with the introduction of nonfullerene acceptors (NFAs). The power conversion efficiency (PCE) of such solar cells has been rising steadily with current champion devices being around 16% of single junction devices and more than 17% of tandem structures. However, the efficiency limit is evaluated to be about 20% for single junction. PCE losses may occur due to open circuit voltage (V_{oc}) loss or short circuit current (J_{sc}) loss where V_{oc} loss through radiative recombination is inevitable. The Holy Grail is to avoid any other losses such that the internal quantum efficiency (IQE) being a ratio between extracted photoelectrons and absorbed photons, is almost 100%, as is indeed the case with some of the state of the art devices. Unfortunately, the high IQE is not accompanied by non-compromised V_{oc} or high fill factor and avoiding the often found trade-off is still a challenge.

Current losses may appear in several steps on the way of converting photon flux to an electric current. Absorption creates excitons that may decay while diffusing towards the donor/acceptor (D/A) interface. After a charge is transferred to the other side of the interface, the charge transfer (CT) state exciton may decay before dissociating to polaron pair. Lastly, polarons may recombine before being collected by the respective contacts. The IQE is a multiplication of exciton to CT, CT dissociation, polarons transport and collection efficiencies. For highly efficient devices, each of these steps should be close to 100% efficient.

There have been many efforts to mitigate this effect, particularly in the material domain. Among various strategies there are morphology control, minimization of binding energy, or inducing ground state energy transfer to accomplish favourable band bending at the junction. It has also been suggested that the inevitable presence of disorder contributes favourably to charge generation.

### General Description

There is a need in the art for a novel solar cell structure configured to provide improved photocurrent at the maximum power point of the solar cell operation.

The underlying physics of the efficiency of rate of transition from bound charge transfer (CT) state to free carrier is of immense importance and has been a topic of intensive investigation. For example, material chemistry has been used to improve cell efficiency providing single Junction efficiency reaching 18%. However, predictions of the maximum efficiency limit places it slightly above 20%. In this context, device design strategies help and bridge the gap.

Additional techniques suggest different device structures that improve the efficiency of organic based solar cells by shifting the contact workfunction, or introducing doping. Initially, doping was used mainly to enhance contact properties and later also as charge recombination layer in multi-junction cells.

Doping is also used in inorganic cells, and, in some configurations, delta-doping (δ-doping) has been introduced in a transport layer, or thin doped layer has been introduced in a wetting layer (spacer) between quantum dots in an active region of the cell. Here too, doping the transport layer resulted in either enhancing its conductivity or charge selectivity. In the field of the organic cells, recently, doping have been introduced also to the bulk of the active region where it was suggested that the dopants may assist in morphology control, trap filling, or maybe screening of the coulomb-binding energy of the CT states.

The present invention provides a solar cell structure configured to provide increased electric field at an active region of the cell including the junction, or charge generation region, of the cell, thereby enhancing charge separation efficiency. The solar cell of the present technique utilizes the active region of the cell formed by a heterojunction interface region and a modulation doping layer located at a selected distance, in vicinity, of the junction. Such modulation doping layer utilizes selected doping to vary electric fields around the junction and enhance charge separation efficiency.

In this connection, it should be understood that with regard to inorganic semiconductor devices, δ-doping typically refers to cases where the doping is confined to a few atomic layers (1-3 mostly). It is called delta (δ) since on both sides of the “zero” width region the semiconductor is undoped.

In cases where the doped region is wider the meaning of δ-doping is not relevant anymore, and such doping actually means that the respective layer is not uniformly doped. So, for example, a 10 nm doped layer within a 40 nm undoped semiconductor constitutes modulation doping.

Thus, the present technique provides solar cells configuration in which an active region is formed by a heterojunction interface region between first and second different materials (e.g. organic or inorganic semiconductors) having different energy band gaps or electronic band structures, and at least one modulation doping layer located at selected distance(s) from the heterojunction interface at, respectively, at least one side of the heterojunction interface. The modulation doping layer(s) is/are of selected predetermined width(s) and doping concentration(s) selected to enhance an electric field, e.g., by varying electronic and hole states' energy variations along a profile of the solar cell.

The solar cell configuration is based on the inventors' understanding that one of the key factors in achieving a high-efficiency solar cell is associated with exciton dissociation (i.e., charge generation) efficiency. In nonfullerene acceptors (NFA) the exciton dissociation may be relatively high if the binding energy is determined using Coulomb attraction between two point charges. Also, several methods indicate that a CT exciton state can be described by a nearest-neighbour pair. This emphasizes the difficulty of dissociating the CT states without significant losses associated with geminate recombination.

Thus, enhanced electric field at the vicinity of the heterojunction can provide increase in charge separation and reduce recombination of exciton generated by absorption of solar radiation. The positive and negative charges (electrons and holes) are pushed in opposite directions due to the enhanced electric field and can be collected with improved efficiency. The inventors have shown that doping directly at the junction might be of a negative effect, but distancing the dopants away from the junction has a positive impact on the device performance.

Thus, according to one broad aspect, the present invention provides a solar cell device comprising a layered structure comprising an electron transport layer and a hole transport layer and a heterojunction interface region between the electron transport and hole transport layers configured to define at least one charge generation region forming at least one junction between them, wherein at least one of the electron transport layer and the hole transport layer comprises at least one modulated doping layer at a predetermined distance from said at least one junction, said at least one modulated doping layer thereby inducing variation of an energy band structure at a vicinity of said at least one junction generating electric field applied to charge carriers increasing efficiency of generation and/or collection of the charge carriers.

According to some embodiments, the predetermined distance of the at least one modulated doping layer from the at least one junction is in a range from about 3 nm to about 60 nm.

According to some embodiments the modulated doping layer has a thickness between about 2 nm and about 25 nm. Preferably, the modulated doping layer has a thickness around 10 nm.

In some embodiments, first and second modulating doping layers are provided being located in the hole transport layer and the electron transport layer, respectively.

According to some embodiments the hole transport layer is p-doped, and modulated doping layer in said electron transport layer is n-doped.

According to some embodiments the modulated doping layer has dopant level higher than 10¹⁶/cm⁻³ or higher than 10¹⁷/cm⁻³.

According to some embodiments the hole transport layer is part of the charge generation region.

According to some embodiments the hole transport layer has higher absorption properties than the electron transport layer, said electron transport layer comprising said modulated doping layer.

According to some embodiments the electron transport layer is part of the charge generation region.

According to some embodiments the electron transport layer has higher absorption properties than the hole transport layer, said hole transport layer comprising said modulated doping layer.

According to some embodiments the solar cell device comprises a first modulated doping layer carrying p-dopant in said hole transport layer and a second modulated doping layer carrying n-dopant in said electron transport layer.

According to some embodiments the solar cell device is implemented in a tandem cell configuration comprising the layered structure described above.

In some embodiments, the heterojunction interface region is configured as a direct interface surface between said electron transport layer and said hole transport layer, defining the junction of the charge generation region. In some other embodiments, the heterojunction interface region is a bulk region whose opposite sides define, respectively, first and second junctions.

The layered structure of the solar cell preferably includes organic material compositions.

According to another broad aspect, the invention provides a solar cell device comprising an electron donor layer and an electron acceptor layer spaced by a heterojunction interface region defining at least one junction between them, at least one of the electron donor layer and the electron acceptor layer comprising a modulated doping layer at a distance between 3 nm and 60 nm from the at least one junction, said modulated doping layer inducing variation of an energy band structure at a vicinity of said at least one junction generating electric field applied to charge carriers increasing efficiency of generation and collection of free charge carriers in said solar cell device.

The invention in its yet further aspect provides a method for improving photocurrent in a solar cell. The method comprises fabricating a layered structure comprising an electron transport layer, a hole transport layer, and a heterojunction interface region between the electron transport and hole transport layers configured to define at least one charge generation region forming at least one junction between them, wherein in at least one of the electron transport layer and the hole transport layer there is at least one modulated doping layer located at a predetermined selected distance from said at least one junction, thereby improving photocurrent at a maximum power point of the solar cell operation

### BRIEF DESCRIPTION OF THE DRAWINGS

In order to better understand the subject matter that is disclosed herein and to exemplify how it may be carried out in practice, embodiments will now be described, by way of non-limiting examples only, with reference to the accompanying drawings, in which:

FIGS. 1A and 1B illustrate examples of solar cell devices according to some embodiments of the present invention utilizing heterojunction structure (FIG. 1A) and charge generation region or bulk heterojunction structure (FIG. 1B);

FIGS. 2A and 2B exemplify TAPC:C70 solar cell configuration (FIG. 2A) and energy band profile (FIG. 2B) of a solar cell device according to some embodiments of the present invention;

FIG. 3 illustrates variation of energy band structure according to some embodiments of the present invention;

FIGS. 4A and 4B show respectively material analysis and scanning microscope image of a device according to some embodiments of the present invention;

FIG. 5 shows dark JV of devices having nominal separation of 0 nm, 10 nm, and nm between the doped-layer and the hetero-junction and of an undoped device;

FIGS. 6A and 6B show the JV curves of the devices; FIG. 6A shows current density versus applied bias of a reference undoped-device and devices with varying separation between the doped-layer and the hetero-junction (as marked on the figure), FIG. 6B shows The JV of FIG. 6A replotted (left axis) along with the current enhancement ratio (left axis);

FIG. 7 shows measured external quantum efficiency (EQE) as a function of excitation wavelength for solar cell device according to the present invention as compared to conventional devices;

FIG. 8 shows External quantum efficiency (EQE) measured as a function of excitation intensity for solar cell device with no modulated doping (undoped), modulated doping at the heterojunction (0 nm) and modulated doping layer at 10 nm distance from the heterojunction (10 nm);

FIGS. 9A and 9B show real (FIG. 9A) and imaginary (FIG. 9B) refractive index of the materials used in the PHJ devices according to some embodiments of the present invention;

FIGS. 10A and 10B show respectively calculated electric field intensity within the device active layers as a function of distance from the CuSCN/TAPC interface and calculated percentage (%) of the power that is absorbed in the first 15 nm of C70;

FIG. 11 shows similar calculations as FIG. 10A determined for wavelength of 550 nm;

FIG. 12 shows measured and simulated current densities as a function of bias and under dark conditions for undoped, 10 nm away and 25 nm away devices according to some embodiments of the present invention;

FIG. 13 shows measured and simulated dark current density as a function of voltage for undoped and 10 nm away doped device using doping concentrations ranging between 10¹⁷, 5*10¹⁷, 10¹⁸ and 10¹⁹;

FIG. 14 shows measured (symbols) and simulated (lines) current densities as a function of bias and under 1 Sun conditions;

FIGS. 15A and 15B show variations of electric potential and electric field in solar cell device according to some embodiments of the present invention; and

FIGS. 16A to 16F show variations in electric potential and energy band structure for bias voltage of 0, 0.6V and 1V and for location of the modulation doping layer at 10 nm and 25 nm according to some embodiments of the present invention.

### DETAILED DESCRIPTION OF EMBODIMENTS

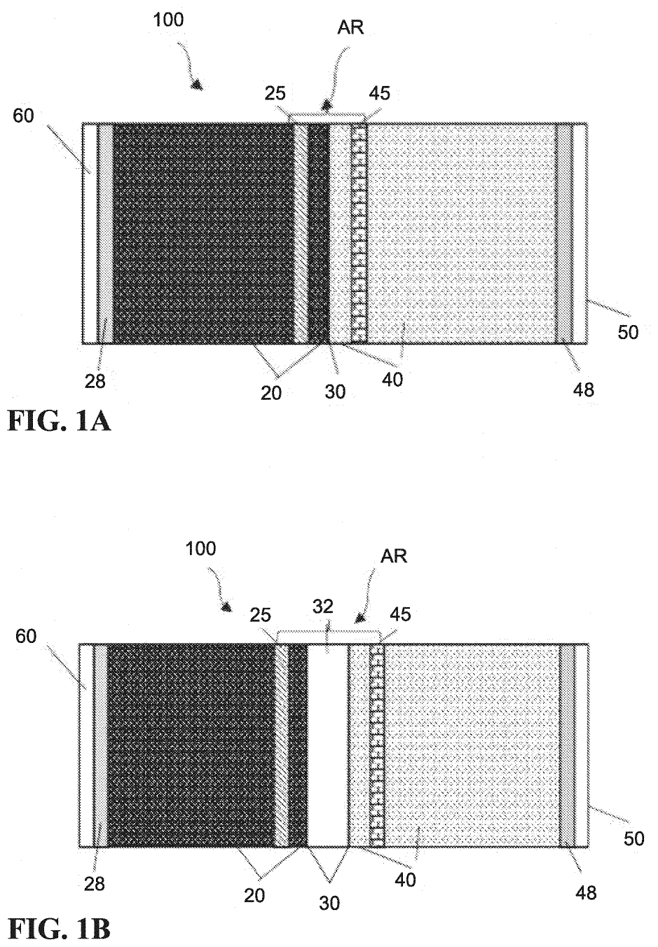

Reference is made to FIGS. 1A and 1B illustrating general configurations of a solar cell structure 100 having different configurations of an active region AR including, respectively, a charge generation region formed by a heterojunction interface surface (FIG. 1A) and a bulk heterojunction layer (FIG. 1B), and at least one modulated doping layer.

In FIG. 1A solar cell 100 is formed of first (acceptor) 20 and second (donor) 40 materials interfacing at heterojunction surface 30. The first and second materials have different energy band structures and different energy band gaps, thereby promoting exciton dissociation to form free charge carriers at the heterojunction interface 30. Additionally, the first and second materials are attached to charge collection electrodes 50 and 60, typically using respective layers of charge selective conductors 28 and 48. According to the invention, the active region AR includes at least one modulated doping layer located within at least one of the first and second materials. As shown in the non-limiting examples of FIGS. 1A and 1B, in some embodiments, both of the first 20 and second 40 materials comprise modulated doping layers 25 and 45.

The modulated doping layer(s) is/are located at some (selected) distance(s) from the heterojunction interface, such that the modulated doping layer is enclosed between the regions of the respective one of the first and second materials. The modulated doping layer(s) 25 and/or 45 is/are formed by doping the respective material to vary the band gap structure at the modulated doping layer, thereby enhancing electric field around the heterojunction of the solar cell, i.e., within the active region of the cell. The modulated doping layer(s) 25 and/or 45 can be of selected predetermined width (being equal or not in case both are used), as well as selected doping concentration/density.

For example, the modulated doping layer is distanced from the heterojunction interface a distance between 5 nm and 25 nm, and may for example be of a width (thickness) in the range of 5 nm to 25 nm.

Due to the width of the doping layer 25 and/or doping layer 45 the respective material(s) 20 and/or 40 is/are doped in a non-uniform manner along the profile of the material(s), thereby generating the effect of the band gap structure variation within the active region affecting variations of the electric field in the vicinity of the heterojunction 30 of the solar cell.

The enhanced electric field provides enhanced exciton dissociation and charge separation efficiency. The inventors have found that placing the doping layers at a selected predetermined distance from the heterojunction interface improves overall performance of the solar cell 100 as shown experimentally further below.

In the example of FIG. 1B, the active region AR the solar cell 100 is formed by a charge generation region 32 in the form of a bulk-heterojunction region (including mixed donor and acceptor materials, or utilizes light absorbing material) whose opposite surfaces 30 interface with the donor 20 and acceptor 40 layers, and at least one of modulated doping layers 25 and 45 within the at least one of the donor and acceptor layers 20 and 40 at some distance(s) from the respective interface surface 30. This predetermined distance can, for example, be in the range of 3 nm to 60 nm.

It should be noted that the solar cells 100 exemplified in FIGS. 1A and 1B could be part of a tandem cell with the required, known, modifications used to tandem the cells.

It should be noted, and is also illustrated in the figures, that a solar cell device utilizing the solar cell structure 100 exemplified in FIGS. 1A and 1B includes electron 28 and hole 48 selective conductors for collecting free charge carriers. It should be understood that these layers may be used or not in accordance with specific construction of the solar cell. For example, the solar cell may include electron selective conductor (e.g. 25), hole selective conductor (e.g. 45), both selective conductors, or utilize selectivity of the first and second materials 20 and 40.

Generally, the modulated doping layer may be of the similar type as the layer being doped. More specifically, the modulated doping layer 25 in the acceptor layer 20 may be n-type doping (n-doped) and the modulated doping 45 in the donor layer 40 may be p-type doping (p-doped). The doping of the modulated doping layer is relatively high, and generally in the range of 10¹⁶ to 10¹⁹ charge carriers per cm⁻³.

The technique of the present invention can be implemented in an organic solar cell structure based on any known suitable combination of material compositions of the functional layers of the solar cell, i.e. electron and hole transport layers (acceptor and donor layers) and modulated doping layer(s).

For example, material compositions commercially available from Sigma-Aldrich can be used. These include, for example, the following acceptor materials: ITIC, ITIC-N, IT-M, ITIC-DM, IT-DM, IT-2M, ITIC-F, FBR, EH-IDTBR, di-PDI, P(NDI20D-T2), N2200, P(NDI2HD-T2), N2300; and the following donor materials: PTB7, PTB7-Th, PCE-10, PBDTTT-C-T, PffBT4T-20D, PffBT4T-C9C13, J51, PBDP-T, PCE-12, PBDTS-TDZ, PDBT-T1.

Any known suitable p-dopant and/or n-dopant may be used to form the modulation doping layer(s) in the at least one of the acceptor and donor layers. For example, the following dopants may be used:

p-Dopant:

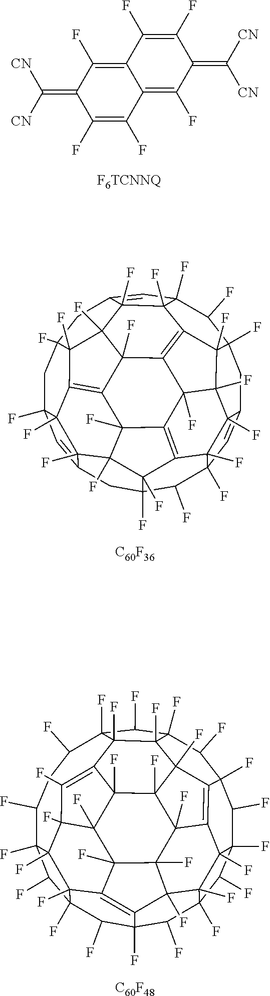

n-Dopant:

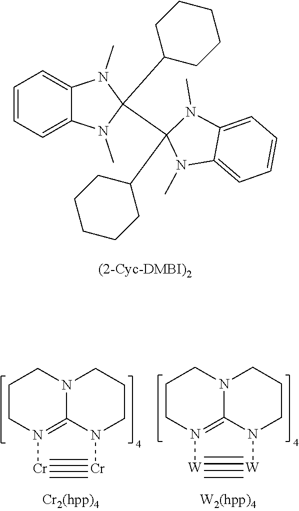

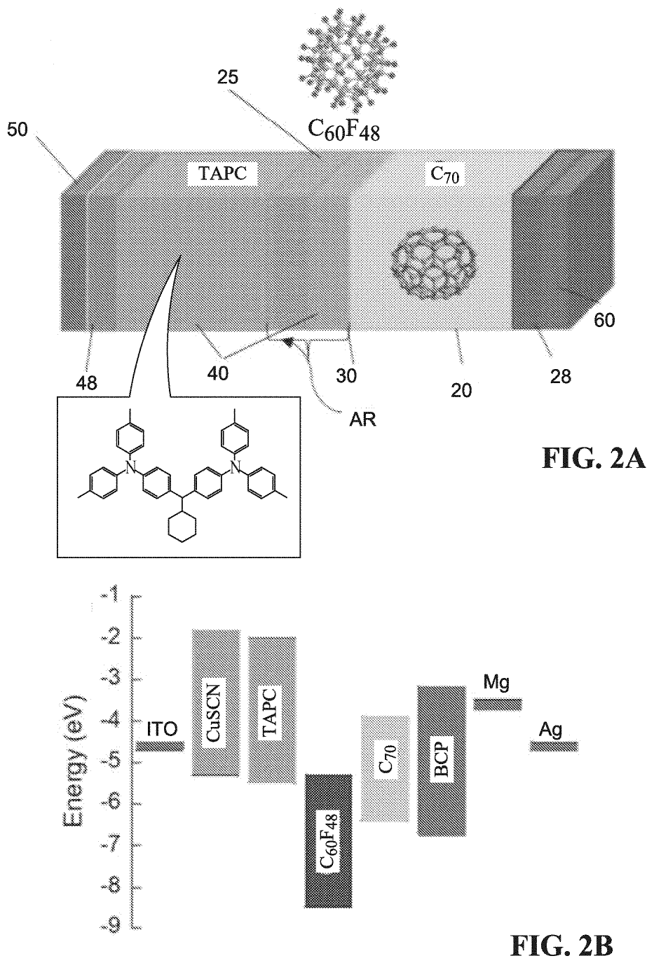

To exemplify the efficiency of the present technique, the inventors have examined modulation-doping using p-dopant C₆₀F₄₈ and the corresponding effect on exciton dissociation and separation efficiency in an organic heterojunction solar cell configuration. FIGS. 2A and 2B exemplify respectively planar solar cell configuration used in this example and diagram of energy band gap variations along axis of the solar cell. To facilitate understanding the functionally similar elements of all the examples are identified by the same reference numbers.

The solar cell configuration exemplified in FIG. 2A is formed of well-studied materials such as C₇₀ and 1,1-bis [(di-4-tolylamino) phenyl] cyclohexane (TAPC) providing variation in energy gap at the heterojunction 30 between the acceptor 20 and donor 40. The second material, TAPC in this example is formed with a modulated doping layer 45, doped with C₆₀F₄₈ dopant at selected concentration. The solar cell d is otherwise as exemplified in FIG. 1A, i.e. including charge selecting layers 28 and 48 and charge collection electrodes 50 and 60 as shown.

The solar cell material combination may be described as ITO/CuSCN/TAPC/C₆₀F₄₈-doped TAPC/TAPC/C₇₀/BCP/Mg/Ag. In this cell configuration ITO provide transparent electrode, CuSCN is hole selective conductor, TAPC and C₇₀ form the heterojunction structure, BCP is an electron selective conductor and Mg and Ag for the back electrode. According to some embodiments, the TAPC layer 40 has a modulated doping layer 45 of C₆₀F₄₈-doped TAPC. FIG. 2B illustrates energy gaps of the layer structure of the solar cell.

Generally, planar heterojunction solar cells may be an advantageous example for the present technique as open circuit voltage of such cells is not limited by the electrodes contact-barriers. The inventors have also experimentally show that modulated doping layer at a selected distance from the heterojunction provides enhance efficiency. This is compared to the conventional configuration as well as configuration where a doping layer is located directly at the junction, which may provide a negative effect.

Measuring low intensity external quantum efficiency (EQE) spectrum as well as intensity dependent quantum efficiency (QE), across 5 orders of magnitude of a solar cell configurations as exemplified in FIG. 2A showed that both the generation and recombination processes are affected by the novel device structure of the present invention. Theoretical investigation of the effect of the dopant's Coulomb potential on the junction's energetic landscape reveals the presence of enhanced local electric field. The results obtained by the inventors show that doping induced potential gradient enhance exciton dissociation, reduce charge recombination, and consequently has a profound effect on the overall device efficiency of the device.

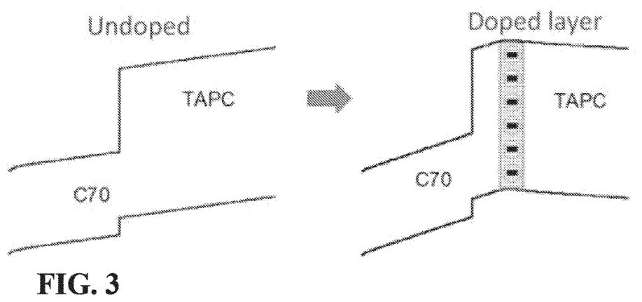

FIG. 3 illustrates energy band diagram of the C70:TAPC junction for the undoped (left) and d-doped (right) device. The diagram of the doped device illustrates also the sheet-charge introduced by the dopants which causes the significant change in the energy level slope. As shown in FIG. 3, the energy band diagram illustrates a gradient in energy formed between the junction and the dopant layer. This gradient indicates electric field being applied on charges in this region, thereby enhancing exciton dissociation and efficiency of the solar cell.

The following is the description of the experimental results obtained by the inventors.

The inventors have experimentally tested solar cell configurations as described above to show the effect of doping a thin layer at the vicinity of and spaced-apart from the donor-acceptor junction on exciton dissociation and charge separation in an organic heterojunction device. The cumulative strength of exciton dissociation and charge separation were measured in differently doped devices by directly measuring their photogenerated current. The experiments were exemplary conducted on TAPC and C₇₀ based small molecule planar heterojunction solar cell and used p-dopant C₆₀F₄₈ to dope a small section of TAPC (i.e. modulation-doping) next to (spaced apart from) the junction. However, it should be understood that the solar cell configurations may utilize other donor-acceptor materials and respective dopants. The schematic of the device structure is shown in FIG. 2A and the energy level diagram of the materials used is presented in FIG. 2B. As indicated above, the present technique is described and investigated herein in a planar heterojunction structure. However, it should be understood that the present technique may be formed in bulk heterojunction structures, e.g., utilizing bi-layer devices. Further, as per the initial discovery that fluorinated fullerenes (C60Fxx) can dope organic semiconductors, fluorinated fullerenes have the advantage of efficient doping as well as stability.

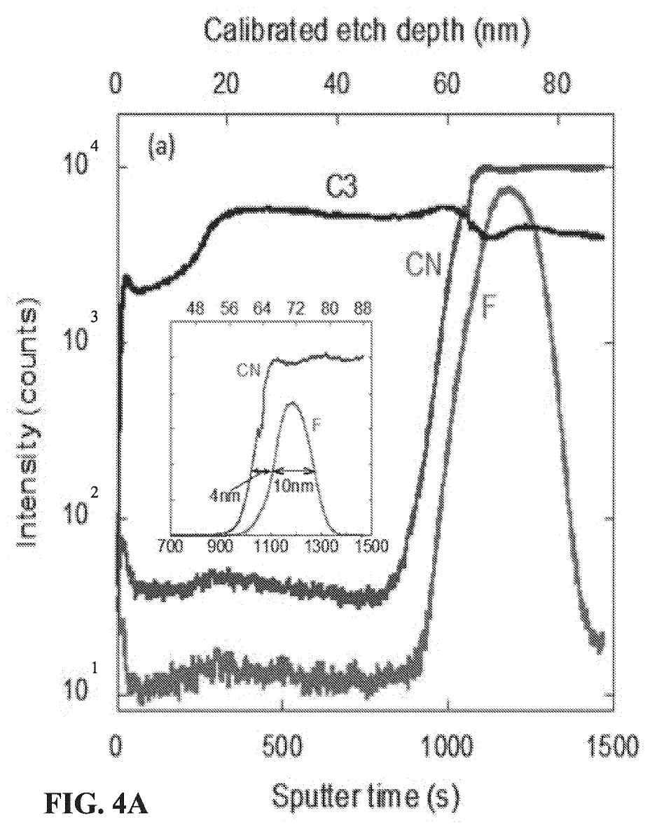

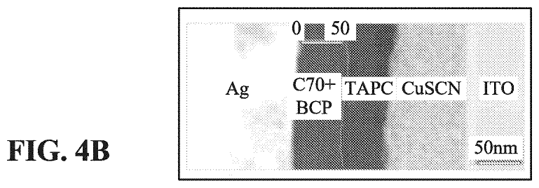

The inventors have constructed a solar cell structure as exemplified in FIG. 2A, having the following nominal layers: C₇₀ (50 nm)/TAPC (10 nm)/TAPC:C₆₀F₄₈ (10 nm)/TAPC (50 nm)/CuSCN (70 nm)/ITO. Due to technical constrains, the measurement was done slightly more than a week following the layers fabrication. This structure was transferred to a Time-of-Flight Secondary Ion Mass Spectrometry (TOF-SIMS) chamber and the relevant elemental analysis is shown in FIGS. 4A and 4B.

FIG. 4A shows chemical analysis and FIG. 4B shows a high resolution scanning tunnelling microscope image of a complete device cross section. The material analysis distinguishing between the materials that are close to the heterojunction is based on the following: C₇₀ has only carbons, only TAPC contains nitrogen, and only C₆₀F₄₈ contains fluorine. As shown in FIG. 4A, the C₆₀F₄₈ dopant is located fully within the TAPC layer and its spatial extension is equal to the nominal value of 10 nm width of the doping layer. The measurement was repeated about a week later using a slower etch rate and the only difference was a slight improvement of the resolution. The complete device illustrated in FIG. 4B shows that the CuSCN layer has slightly uneven surface and that the active layer conforms to it. Also, the thickness of the C₇₀ layer is similar to the one deduced from the SIMS data.

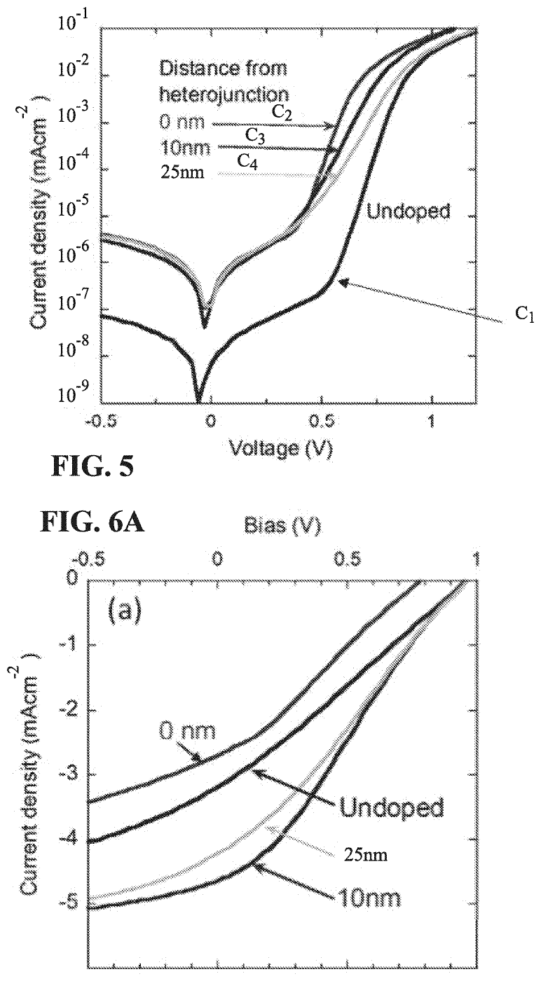

Additionally, the inventors have tested the experimental structures for the potential effect of the doped layer as compared to the conventional solar cell configuration. To this end, a series of devices/structures has been fabricated with the varying parameter being the thickness of the undoped region to be inserted between the thin-doped layer and the heterojunction. FIG. 5 shows dark J-V curves (measured in the dark) corresponding to current density J versus applied bias voltage V for a reference undoped device (curve C₁) and for devices with varying separation between the doped-layer (modulated doping) and the heterojunction, i.e., nominal separation of 0 nm, 10 nm, and 25 nm (curves C₂, C₃ and C₄ respectively) between the modulated doping layer and the heterojunction. The overall thickness of TAPC with the modulated doping layer was kept the same in all the devices.

As shown in FIG. 5, upon adding the modulated doping layer the reverse leakage current at −0.5V increases from 70 pAcm⁻² to ˜3.5 nAcm⁻² indicating an enhanced conductivity of the device. Also, the diodes ideality factor (exponential rise n) was measured changing between values of n=1.1 (undoped), n=1.4 (0 nm), n=1.8 (10 nm), and n=2 (25 nm).

First, these differences show that positioning of the modulated doping layer is accurate and stable enough to allow for this fine spatial resolution, in agreement with FIGS. 4A and 4B. Second, the standard TAPC:C₇₀ diode used as reference diode, was extensively analysed in the art and despite n−1 the recombination was found to be composed of both Langevin-like bimolecular and trap-assisted recombination. The trend of the doped devices suggests that the monomolecular recombination becomes more dominant. However, the presence of the modulation-doping (modulated doping layer) makes these devices to be non-standard ones.

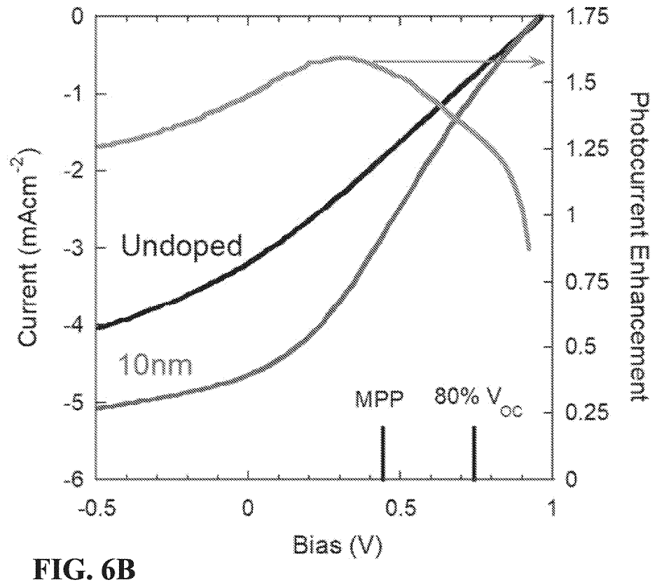

Having established that the position of the modulated doping layer affects the device characteristics, its effect on the photocurrent conversion efficiency (PCE) are examined. FIGS. 6A to 6B show the J-V curves of the same devices as in FIG. 5 but measured under one sun illumination.

FIG. 6A shows current density versus applied bias for a reference undoped-device and devices with varying separation between the doped-layer and the heterojunction (as marked on the figure). FIG. 6B shows the J-V curves of FIG. 6A replotted (left axis) along with the current enhancement ratio (left axis). As shown, doping just at the junction (0 nm) degrades the device performance by primarily shifting the open circuit voltage (V_{OC}) from 0.95 V to 0.77 V. Distancing the modulated doping layer from the heterojunction, e.g. by 10 nm, recovers the V_{OC} and significantly improves both the fill factor and the short circuit current (J_{SC}). The short circuit current J_{SC} of the device with the modulated doping layer 10 nm away is 46% higher compared to that of the undoped device. Moving the modulated doping layer even farther reduces the efficiency only slightly as the J-V curve changes slightly towards the undoped case.

To quantify the improvement of the extracted current by placing the modulated doping layer away from the junction (e.g. 10 nm away), FIG. 6B shows the PCE for the undoped diode and the diode with such modulated doping layer distanced from the heterojunction and overlay on it the ratio between the two. The maximum power point (MPP) is measured slightly below 0.5V (see FIG. 6B) and at this bias the current enhancement is 55%. Generally, in suitable solar cell, the MPP may be closer to V_{OC}. At V=0.8V_{OC} the enhancement is 32% and at V=0.9V_{OC} it is 15%.

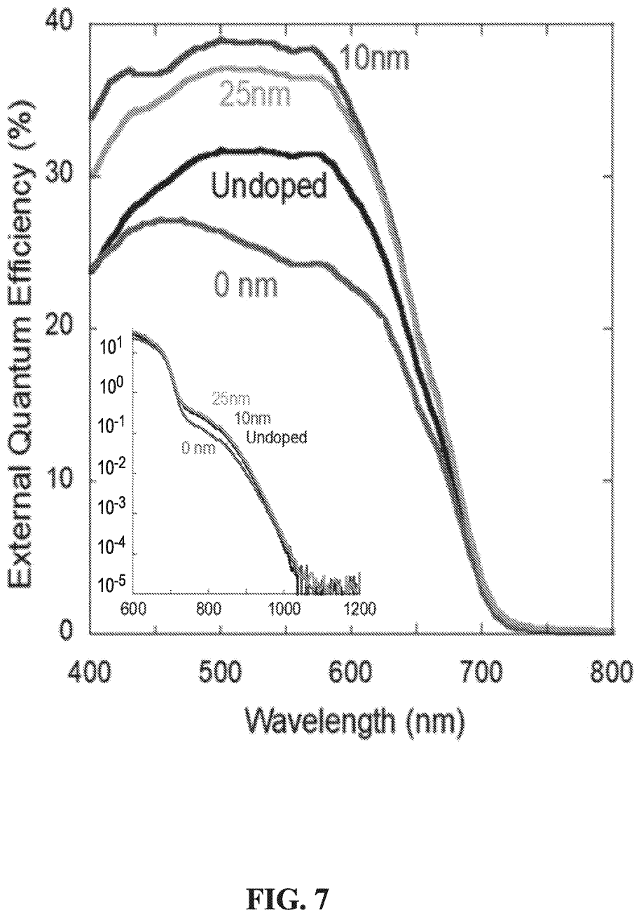

Reference is made to FIG. 7 showing spectrally resolved external quantum efficiency (EQE) measured as a function of excitation wavelength for the solar cell devices used in the previous experiments, i.e., the undoped device and devices with different locations of the modulated doping layer.

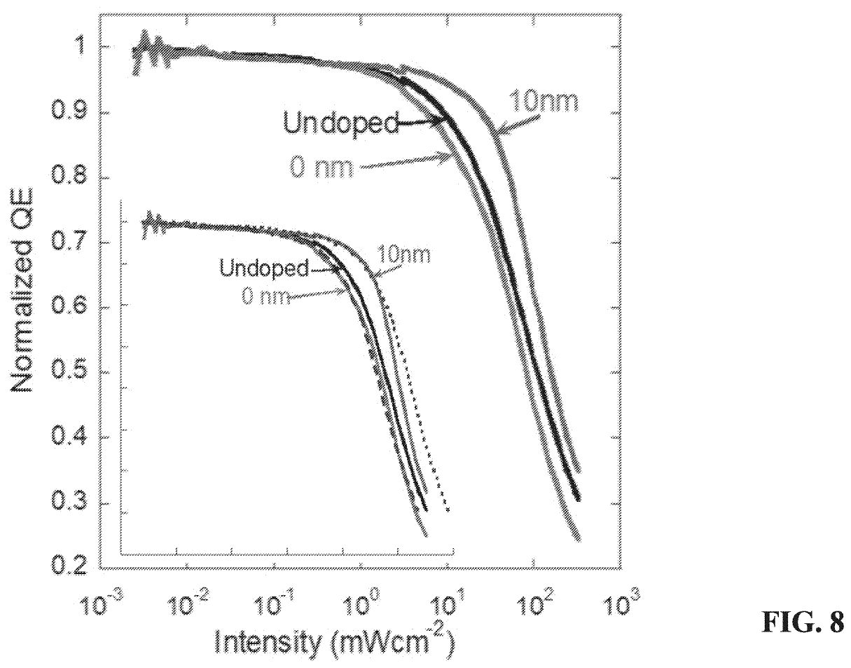

This measurement used low light intensity for the four device structures. The inset in FIG. 7 shows the same data on logarithmic scale emphasizing the sub-gap absorption. The excitation intensity was kept below 1 mWcm⁻² so as to be in the intensity independent regime (shown in FIG. 8 below as plateau part of the curve). The relative values in the 400-700 nm range are in line with the trend found for the J_{SC} currents. The sub-gap EQE shows indeed that doping away from the junction has no effect on the sub-gap states at the junction. Doping at the junction, however, seems to slightly reduce the optical activity of the sub gap states.

The VIS part of the EQE shown in FIG. 7 has two significant features. First, the EQE of the device sample using 10 nm distance between the heterojunction and modulated doping layer (10 nm away device) is only about 25% higher compared to that of the undoped device, where the J_{SC} showed 46% enhancement. Second, the spectral shape of the device with the modulated doping layer distanced from (10 nm distance in this example) the junction is different to the undoped device. The difference between the 25% of the EQE and the 46% of the J_{SC} might be associated with the vastly different excitation density used in the two cases (>2-3 order of magnitude difference).

Reference is made to FIG. 8 showing external quantum efficiency measured as a function of excitation intensity for solar cell device with no modulated doping (undoped), modulated doping at the heterojunction (0 nm) and modulated doping layer distanced (e.g. at 10 nm distance) from the heterojunction (10 nm). The curves were normalized to their low intensity part. Excitation source was white LED. Inset shows the same data plus the curve of the undoped device shifted to low intensity (dashed line) and to high intensity (dotted line). Generally, at very low light intensity the device's quantum efficiency is intensity independent and in most cases represents the free charge generation efficiency. The plateau in the EQE versus intensity is then followed by a decline in efficiency as higher order losses kick in. The position of the “knee” that marks the initial decay in EQE is a function of the interplay between the charge recombination and the charge extraction. If one of these parameters is known, this curve can be used to deduce the other of these parameters; or in cases that the two parameters are interlinked, both of them can be directly deduced.

FIG. 8 shows that the higher order (>1) losses kick is at different intensities for the undoped, junction doped (0 nm), and distance (e.g. 10 nm) away doped devices. Namely, compared to the reference device, the recombination for the junction-doped and the 10 nm away doped devices is more and less effective, respectively. Since for the e.g. 10 nm away the dopants are clear of the junction, the recombination is not affected and the extraction from the junction area becomes more efficient. This may be explained by that if the physical mechanisms do not change and only their relative magnitudes, then shifting the curves horizontally would result in perfect overlap. The inset to FIG. 8 shows the same data as the main figure plus the curve for the reference (undoped) device shifted to lower (dashed) and higher (dotted) intensities. In the case of the junction-doped (0 nm) device, a perfect overlap is obtained indicating that the only thing that happened is that the recombination became more significant. For the device with the modulated doping layer distanced (e.g. 10 nm) from the junction it is impossible to obtain overlap across a wide range and hence the physical processes have changed. To address this point, let us consider optical and electrical modeling.

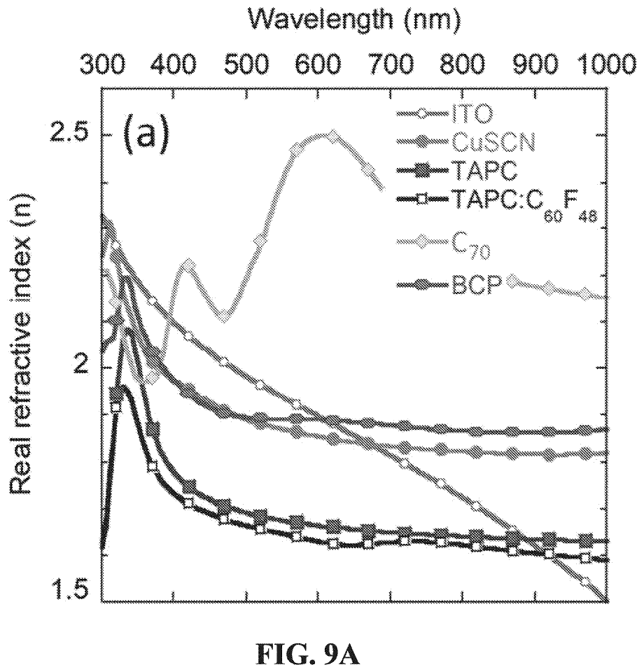

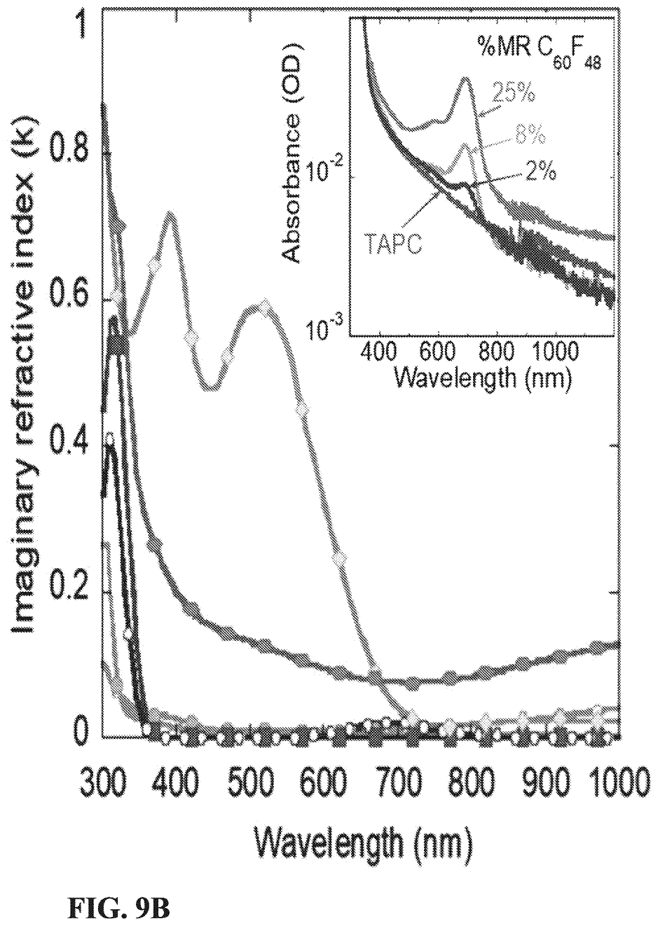

Referring back to FIG. 7, there is demonstrated that not only the absolute value of the EQE spectrum changes between devices but also the shape. A change in the shape is often attributed to interference effects, hence the electric field distribution and the absorption as a function of wavelength can be determined. In this connection, reference is made to FIGS. 9A and 9B showing Real part (FIG. 9A) and Imaginary part (FIG. 9B) of the refractive index of the materials used in the PHI devices. The inset in FIG. 9B is the absorbance spectrum of ˜70 nm thick undoped TAPC and 25%, 8%, 2% molar ratio C₆₀F₄₈ in TAPC.

The real and imaginary parts of the refractive indices of the doped and undoped TAPC are very similar but for a tiny hump at about 700 nm associated with the doping induced polaron absorption. The inset in FIG. 9B shows the absorbance of TAPC at different levels of molar ratio % (MR %) doping confirming the presence of the doping induced absorption (film thickness ˜70 nm).

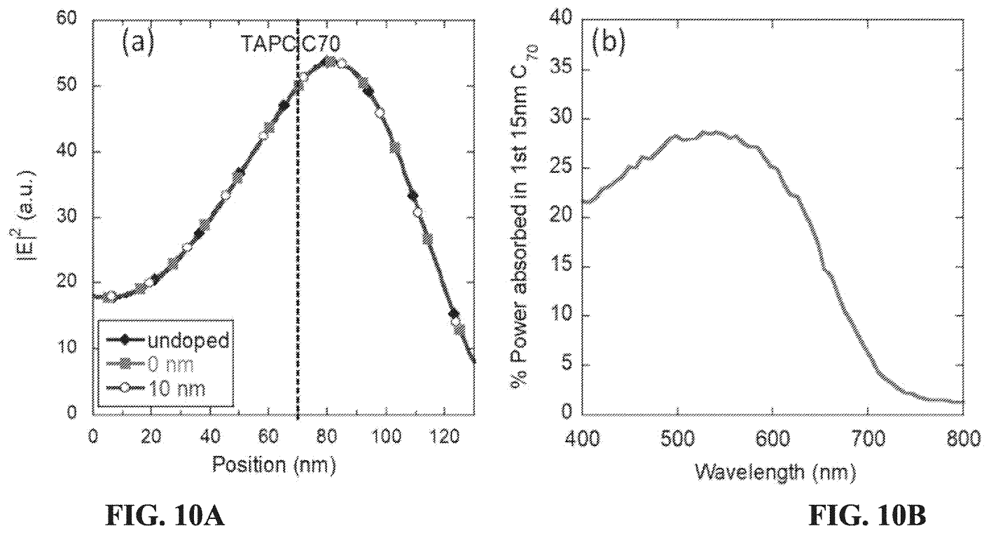

Additionally, reference is made to FIGS. 10A and 10B showing, respectively, the calculated wavelength-integrated electric field intensity distribution within the device as a function of distance from the CuSCN/TAPC interface, and the calculated percentage (%) of the power that is absorbed in the first 15 nm of C70 (70 nm-85 nm in FIG. 10A). The electric field calculation FIG. 10A shows an integration over the wavelength range 450 nm-700 nm. The calculations were done for the various device structures yielding indistinguishable results.

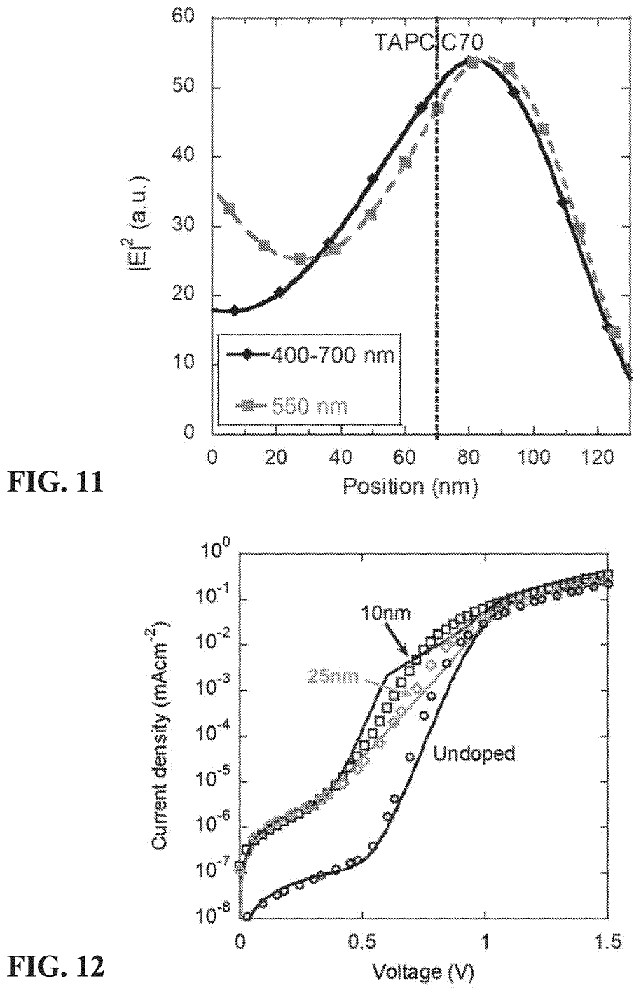

For the calculation shown in FIG. 10A, the intensity was integrated across 450 nm to 700 nm and the vertical dashed line denotes the TAPC/C₇₀ interface. Similar calculation for 550 nm only is shown in FIG. 11. As the figure shows, since the doping hardly affected the refractive indices, there is no difference in the field distribution within the TAPC layer between the different device structures. FIG. 10B shows the power absorbed in the device in the first 15 nm of C₇₀ from the junction. The selection of 15 nm is a generally reasonable value for the exciton collection by the junction. The resulting spectral shape is very similar to the measured reference (undoped) device.

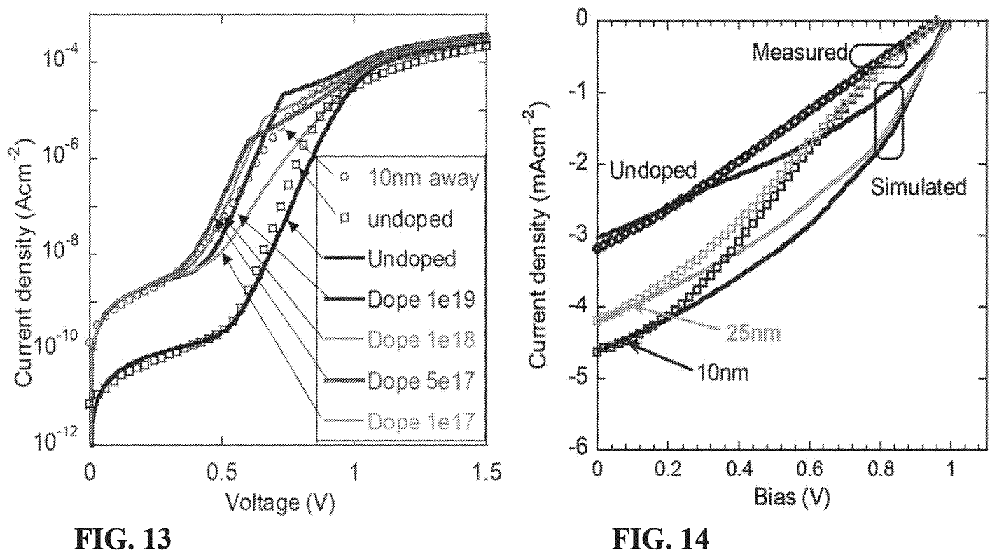

Reference is now made to FIG. 12 showing measured (symbols) and simulated (lines) current densities as a function of bias and under dark conditions for undoped, 10 nm away and 25 nm away devices. The doped devices were simulated based on a 10 nm thick TAPC doped layer (at concentration of 5×10¹⁷ cm⁻³) positioned 10 nm or 25 nm away from the junction. Parallel (leakage) resistance of 3×10⁶Ω and 10⁵Ω was manually added for the undoped and doped devices, respectively. The parameters for the different device structures were kept constant, but for the 10 nm thick doped (5×10¹⁷ p-type) layer that was positioned either 10 nm or 25 nm away from the junction. Using the absorption of the charge-transfer (CT at ˜700 nm) to estimate the doping efficiency of C₆₀F₄₈ as a function of the host ionization energy suggests that the doping may be as high as 10¹⁹ cm⁻³. It has been shown that the fraction of CT that dissociate into free charges can be as low as 10% of the values extracted through absorption. Simulating a range of doping levels, the inventors have shown that the quality of the fit did not improve above 5×10¹⁷ cm⁻³. This is illustrated in FIG. 13 showing measured and simulated dark current density as a function of voltage for undoped and 10 nm away doped device using doping concentrations ranging between 10¹⁷, 5*10¹⁷, 10¹⁸ and 10¹⁹. Doping above 5×10¹⁷ cm⁻³ shows substantially similar results. The agreement between the experimental and simulated results in FIG. 12 is indicative of that the main difference between the devices is captured by a drift-diffusion-Poisson based model.

To confirm that the differences between the three device structures are on the device level, the inventors also simulated the J-V curve under sun illumination. Simulating using Sentaurus, the process of CT excitons splitting at the junction as well as the exciton binding energy that may be hindering it were generally not implemented. To mimic these effects and come close to the real physics, the following scenario was used:

1. Generation of free electrons and holes and only at the first 10 nm of C₇₀. Namely, holes are close enough to the TAPC interface so that they can diffuse to it.

2. To mimic the effect that the charges should not be generated as being free to move the inventors introduced high bimolecular and monomolecular recombination into these 10 nm. This way, if charges are not swept-out efficiently they would recombine.

Reference is made to FIG. 14 showing measured (symbols) and simulated (lines) current densities as a function of bias and under 1 Sun conditions. The doped devices were used with a 10 nm thick TAPC doped (5×1017 cm-3) layer positioned 10 nm or 25 nm away from the junction. As indicated above, the generation and recombination parameters were chosen such that the simulation of the undoped (reference) device is as close as possible to the measured J-V curve. Next, 10 nm doped layer was inserted, and the simulation was repeated. It should be noted that the J-V enhancement for the 10 nm away from the junction, and the slight decline for the 25 nm away, are in excellent agreement with the trend found in the measured data. Namely, the performance enhancement is indeed mostly on the device level and variations in material and basic processes are, at best, secondary.

Having deduced that the enhancement is on the device level the entire set of internal data produced by the simulations can be used and the source can be identified.

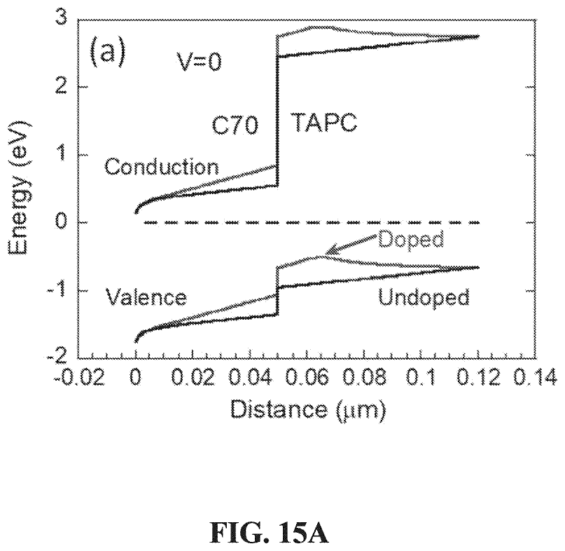

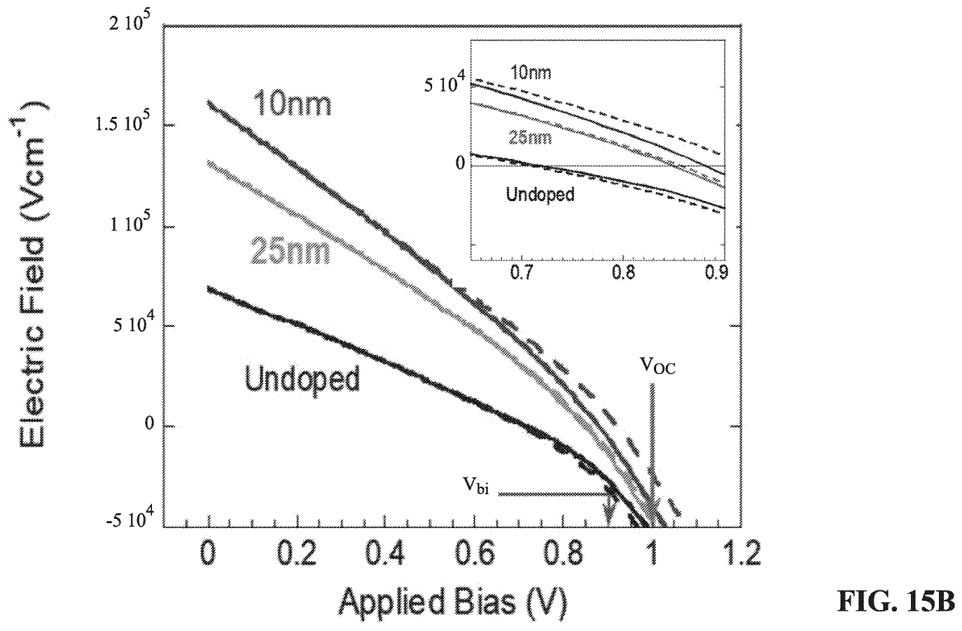

Reference is made to FIGS. 15A and 15B showing the effects that led to the efficiency enhancement. FIG. 15A illustrates energy band diagram at V=0 for the undoped and 10 nm away doped. The dashed line is the Fermi level that serves as reference. FIG. 15B shows internal electric field at 5 nm distance from the junction for the undoped, 10 nm away, and 25 nm away devices. The full and dashed lines are values for the field on the C₇₀ and TAPC sides, respectively. The arrows mark V_{bi}=0.9V and V_{OC}=1V, respectively. The inset in FIG. 15B is a zoom of the range, just below V_{bi}, that is governed by diffusion.

As shown, the energy level diagram at short-circuit, for the reference (undoped) device, has its standard shape with the levels being linearly tilted to indicate the internal electric field associated with the energy difference between the two contacts (V_{bi}). For the 10 nm away doped device the doped-layer provides a gradual change in the energy levels that results even in a sign flip of the slope (electric field) between its two sides. The implication is that by modulation-doping the hole transport layer, the entire region between the doped-layer and the cathode experiences higher internal electric field.

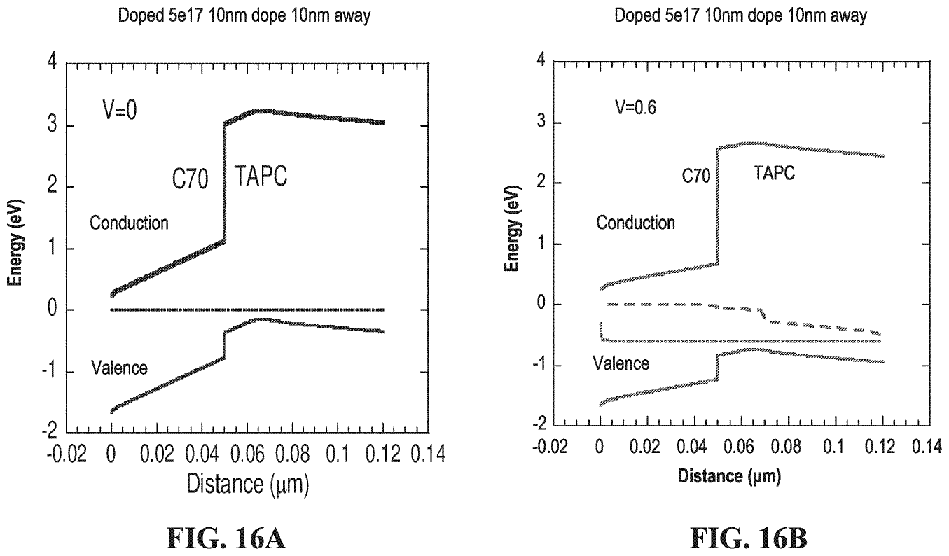

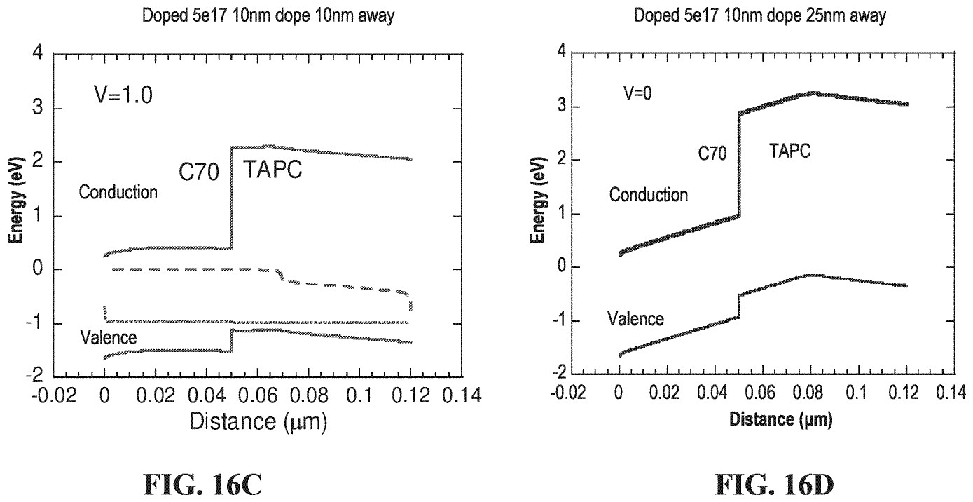

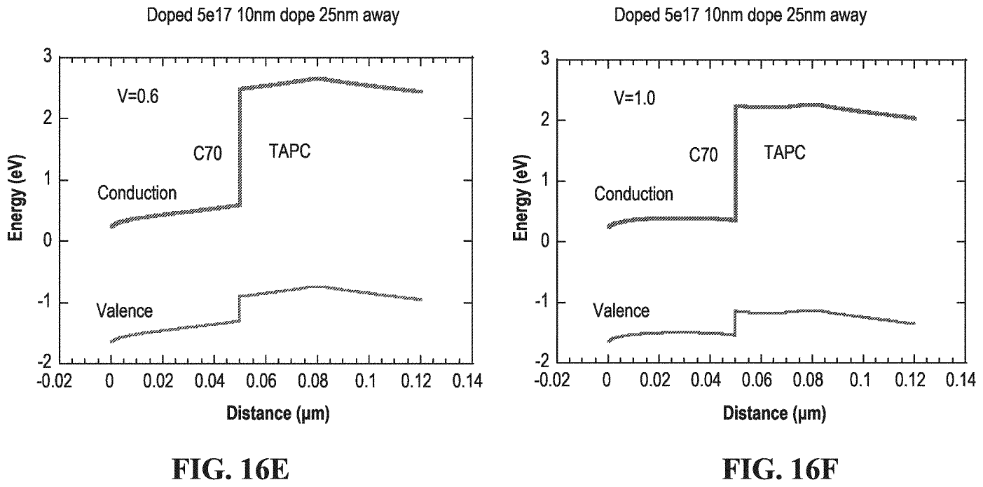

FIGS. 16A to 16F show additional energy level diagrams for bias levels of 0V, 0.6V and 1V (FIGS. 16A to 16C), and for the 25 nm away device with bias levels of 0V, 0.6V and 1V (FIGS. 16D to 16F). These figures show that as the doped region moves away from the junction so does the point at which the electric field switches sign. A larger distance between this “switching point” and the cathode results in a slightly lowered slope (E field).

To quantify the electric field enhancement reference is made back to FIG. 15B, showing the electric field at the two sides of the junction and for three device structures: undoped, 10 nm away doped, and 25 nm away. The V_{OC} which is almost identical for the three, and V_{bi}, are marked by arrows. It should be noted that for the p-type modulation-doping the hole transport layer has significantly enhanced the internal electric field between the doped-layer and the cathode. It is known that as the solar cell approaches the built-in potential (V_{bi}=0.9V) the device enters the diffusion-controlled regime. The inset to FIG. 15B shows a zoomed in view of the range just below V_{bi} and it is striking how by introducing modulation-doping, the field-assisted regime extends by 0.15V.

All devices used in the experiments were fabricated on top of an indium tin oxide (ITO) coated glass substrate. To suppress any perimeter leakage, the ITO substrates were covered with 350 nm polyimide layer leaving a diode active area of 25 mm². The ITO substrates were cleaned in an ultrasonic bath of acetone, methanol, and 2-propanol for 30 min each and dried in a flow of nitrogen. The substrates were further dried in an oven at 1000 C for 60 min. Next, followed by a 15 minute ozonation, a 70 nm thick hole transport layer (HTL) of copper thiocyanate (CuSCN, Sigma 99%) was deposited by spin-coating. For this purpose, a 30 mg/ml solution of CuSCN dissolved in diethyl sulfide (DES) was stirred and filtered (0.45 m PTFE). The films were spin-coated inside a nitrogen-filled glovebox and annealed at 100° C. for 20 min in nitrogen rich environment. Directly afterwards, a 70 nm thick film (1 A0/s) of 4,4′-cyclohexylidenebis[N,N-bis(4-methylphenyl)benzenamine] (TAPC from Lumtec, UHP) as donor, a 50 nm thick film (0.4 A0/s) of C70 (Lumtec, UHP) as an acceptor, a 8 nm thick (0.5 A0/s) wide-energy-gap material 2,9-dimethyl-4,7-diphenyl-1,10-phenanthroline (BCP, Sigma-Aldrich, purity 99.99%) as the hole/exciton blocking layer, and 30 nm thick Mg (1 A0/s) covered with a 120 nm thick Ag (1 A0/s) were thermally evaporated in a commercial vacuum deposition system (VINCI Technologies) at a base pressure of 2×10⁻⁷ mbar. The control device referred to herein as undoped device had ITO/CuSCN (70 nm)/TAPC (70 nm)/C₇₀ (50 nm)/BCP (8 nm)/Mg (30 nm)/Ag (120 nm) structure.

In doped structures where a section of TAPC layer away from the TAPC/C₇₀ interface was doped, TAPC was co-evaporated with fluorinated fullerene (C₆₀F₄₈), a p-dopant, resulting in a doped TAPC layer. To achieve this, TAPC (1 Å/s) and C₆₀F₄₈ (0.08 Å/s) rates were separately monitored using two independent quartz crystal microbalance (QCM) sensors. The junction doped device was fabricated within structure ITO/CuSCN (70 nm)/TAPC (60 nm)/TAPC:C₆₀F₄₈ (10 nm)/C₇₀ (50 nm)/BCP (8 nm)/Mg (30 nm)/Ag (120 nm). Devices with doping away from the interface had structure ITO/CuSCN (70 nm)/TAPC (60-X nm)/TAPC:C₆₀F₄₈ (10 nm)/TAPC (X nm)/C₇₀ (50 nm)/BCP (8 nm)/Mg (30 nm)/Ag (120 nm) in which modulated doping layer was shifted X nm (X=0-25 nm or 0, 10, 25 nm) away from the TAPC/C₇₀ interface.

The dark current-voltage of organic photo diodes (OPDs) were characterized with a semiconductor parameter analyser (B1500 A, Agilent Technologies) inside a nitrogen-filled glovebox. Power conversion efficiencies (PCE) were calculated under AM1.5 G solar illumination (Oriel Sol 3A Class AAA) at 100 mW cm-2 (1 sun) with Keithley 2400 source. Intensity-dependent photocurrent was measured using a white light emitting diode matrices, whose intensity was controlled by the bias current. Appropriate optical density (OD) filters were used to extend the intensity range (˜5 orders of magnitude) from ˜3×10-5-5 Sun to ˜3 Sun intensity. Spectrally resolved EQE was performed outside the glove box with measured samples kept in nitrogen atmosphere inside a holder measured using light from the monochromator (Cornerstone™ 130) was chopped at 80 Hz, and the signal was read using a lock-in amplifier (EG & G 7265). All optoelectrical characterizations were performed outside the glove box with measured samples kept in nitrogen atmosphere inside a holder.

Optical absorption measurements of TAPC, C₆₀F₄₈, and doped TAPC layer (TAPC:C₆₀F₄₈) on glass was done using a UV-Vis-NIR spectrophotometer (Cary 5000, Agilent) in air.

The ellipsometry measurements of various films present in the device were conducted by variable angle spectroscopic ellipsometry (VASE Ellipsometer J.A. Woollam Co.) model. Films of 50 nm thickness were deposited on a glass substrate and were characterized using the VASE ellipsometer at different angles (60, 65, and 70 degrees) in the wavelength range from 300 to 1000 nm. The fitting of the measured data was done by using the appropriate oscillators (a superposition of the Gaussian and Lorentz oscillators).

TOF-SIMS measurements were performed using ION-TOF GmbH TOF-SIMS 5 (located at the Technion, Israel Institute of Technology). The depth profiles were taken in a dual mode using 15 keV Bi+ analysis ions and 1 keV Cs+ as the sputtering ions (incident at 450) at an average etch rate of 0.06 nm/s. The sputtered area for all measurements was 300×300 m², and the acquisition area was 50×50 μm² Distribution of electric field intensity within the device and consequently the light absorption was calculated using an optical model based on transfer matrix formalism. The model takes into account the interference effects in the calculation. The model calculates optical electric field intensity distribution as a function of position once the input parameters, complex refractive index (n, k) and thicknesses of all layers are provided. From the electric field intensity distribution power absorption as a function of depth is calculated using Poynting formula.

The simulations have been performed using Sentaurus device simulator by Synopsis. The simulated device structure was based on the configuration exemplified in FIG. 2A but typically ignored the selective conducting layers (such as CuSCN and BCP layers) assuming that the contacts were directly attached to the TAPD and C₇₀ layers. Device parameters were tuned around their literature values to obtain the measured dark and light current measured for the undoped (reference) device. The recombination at the junction was modelled using “surface SRH recombination” with the trap defined at midgap with the effective recombination velocity being 10⁴ cms⁻¹. The density of states (DOS) was defined as Gaussian with s=70 meV and total DOS was 10²⁰ cm⁻³. Mobility values were taken as 2×10⁻⁴ cm²v⁻¹s⁻¹. The statistics used was Fermi.

Thus, the present invention provides a solar cell configuration utilizing a thin doped layer (modulation-doping) located within the transport layer. The solar cell of the present invention enhances the solar cell's efficiency in a significant manner. To minimize the ambiguity, the results interpretation used a bilayer planar heterojunction and utilized well known and characterized materials (TAPC & C₇₀). However, the present technique should be understood broadly as utilizing modulated doping of one or two of the transport layers, where the hole transport layer may be p-doped and/or the electron transport layer may be n-doped. Preferably, the modulated doping obtained using doping layer of a width ranging between 5 nm and 20 nm and located at distance of 5 nm-30 nm from the junction may be used. Also, in the present examples the doping is of the wide bandgap TAPC layer to eliminate direct interaction between the dopants and the excitons that are generated only in the C₇₀ layer. Where other materials are used, it is preferable that the doping is on the transport layer having lower solar absorption properties.

1. A solar cell device comprising a layered structure comprising an electron transport layer and a hole transport layer and a heterojunction interface region between the electron transport and hole transport layers configured to define at least one charge generation region forming at least one junction between them, wherein at least one of the electron transport layer and the hole transport layer comprises at least one modulated doping layer at a predetermined distance from said at least one junction, said at least one modulated doping layer thereby inducing variation of an energy band structure at a vicinity of said at least one junction generating electric field applied to charge carriers increasing efficiency of generation and/or collection of the charge carriers.

2. The solar cell device of claim 1, wherein the predetermined distance of the at least one modulated doping layer from the at least one junction is in a range from about 3 nm to about 60 nm.

3. The solar cell device claim 1, wherein said at least one modulated doping layer has a thickness between about 2 nm and about 25 nm.

4. The solar cell device of claim 3, wherein said at least one modulated doping layer has a thickness of about 10 nm.

5. The solar cell device of claim 1, wherein said at least one modulating doping layer comprises first and second modulating doping layers located in the hole transport layer and the electron transport layer, respectively.

6. The solar cell device of claim 5, wherein the modulated doping layer in said hole transport layer is p-doped, and the modulated doping layer in said electron transport layer is n-doped.

7. The solar cell device of claim 1, wherein said at least one modulated doping layer has dopant level higher than 10¹⁶/cm⁻³.

8. The solar cell device of claim 1, wherein said at least one modulated doping layer has dopant level higher than 10¹⁷/cm⁻³.

9. The solar cell device of claim 1, wherein said hole transport layer is part of the charge generation region.

10. The solar cell device of claim 1, wherein said hole transport layer has higher absorption properties than the electron transport layer, said electron transport layer comprising said modulated doping layer.

11. The solar cell device of claim 1, wherein said electron transport layer is part of the charge generation region.

12. The solar cell device of claim 1, wherein said electron transport layer has higher absorption properties than the hole transport layer, said hole transport layer comprises said modulated doping layer.

13. The solar cell device of claim 1, comprising a tandem solar cell configuration utilizing said layered structure.

14. The solar cell device according to claim 1, wherein said heterojunction interface region is configured as a direct interface surface between said electron transport layer and said hole transport layer, defining the junction of the charge generation region.

15. The solar cell device according to claim 1, wherein said heterojunction interface region is a bulk region whose opposite sides define, respectively, first and second junctions.

16. The solar cell device according to claim 1, wherein said layered structure comprises organic material compositions.

17. A solar cell device comprising an electron donor layer and an electron acceptor layer spaced by a heterojunction interface region defining at least one junction between them, at least one of the electron donor layer and the electron acceptor layer comprising a modulated doping layer at a distance between 3 nm and 60 nm from the at least one junction, said modulated doping layer inducing variation of an energy band structure at a vicinity of said at least one junction generating electric field applied to charge carriers increasing efficiency of generation and collection of free charge carriers in said solar cell device.

18. A method for improving photocurrent in a solar cell, the method comprising fabricating a layered structure comprising an electron transport layer, a hole transport layer, and a heterojunction interface region between the electron transport and hole transport layers configured to define at least one charge generation region forming at least one junction between them, wherein in at least one of the electron transport layer and the hole transport layer there is at least one modulated doping layer located at a predetermined selected distance from said at least one junction, thereby improving photocurrent at a maximum power point of the solar cell operation.
